(19) United States
(12) Patent Application Publication
(10) Pub. No.: US 2014/0009887 A1
(43) Pub. Date: Jan. 9, 2014

(54) FLUORINATED OXIRANES AS HEAT TRANSFER FLUIDS

(71) Applicants: Bamidele Fayemi, St. Paul, MN (US); Zhongxing Zhang, Woodbury, MN (US); Michael G. Costello, Afton, MN (US); Michael J. Bulinski, Houlton, WI (US); John G. Owens, Woodbury, MN (US); Phillip E. Tuma, Faribault, MN (US); Richard M. Minday, Stillwater, MN (US); Richard M. Flynn, Mahtomedi, MN (US)

(72) Inventors: Bamidele Fayemi, St. Paul, MN (US); Zhongxing Zhang, Woodbury, MN (US); Michael G. Costello, Afton, MN (US); Michael J. Bulinski, Houlton, WI (US); John G. Owens, Woodbury, MN (US); Phillip E. Tuma, Faribault, MN (US); Richard M. Minday, Stillwater, MN (US); Richard M. Flynn, Mahtomedi, MN (US)

(73) Assignee: 3M INNOVATIVE PROPERTIES COMPANY, St. Paul, MN (US)

(21) Appl. No.: 14/007,041

(22) PCT Filed: Mar. 19, 2012
(86) PCT No.: PCT/US12/29649

§ 371 Date: Sep. 24, 2013

Related U.S. Application Data
(60) Provisional application No. 61/467,432, filed on Mar. 25, 2011.

(51) Int. Cl. H05K 7/20

(52) U.S. Cl. CPC H05K 7/20218
USPC 361/699; 165/104.11; 361/679.01

(57) ABSTRACT

A apparatus and a method for heat transfer is provided. The apparatus include a device and a mechanism for transferring heat to or from the device that includes a heat transfer fluid comprising a fluorinated oxirane. The fluorinated oxirane can contain substantially no hydrogen atoms bonded to carbon atoms and can have from about 4 to about 18 carbon atoms.

### FIELD

This disclosure relates to apparatuses and methods that include fluorinated oxiranes as heat-transfer fluids.

### BACKGROUND

Presently various fluids are used for heat transfer. The suitability of the heat-transfer fluid depends upon the application process. For example, some electronic applications require a heat-transfer fluid which is inert, has a high dielectric strength, has low toxicity, good environmental properties, and good heat transfer properties over a wide temperature range. Other applications require precise temperature control and thus the heat-transfer fluid is required to be a single phase over the entire process temperature range and the heat-transfer fluid properties are required to be predictable, i.e., the composition remains relatively constant so that the viscosity, boiling point, etc. can be predicted so that a precise temperature can be maintained and so that the equipment can be appropriately designed.

Perfluorocarbons and perfluoropolyethers (PFPEs) have been used for heat-transfer. Perfluorocarbons (PFCs) can have high dielectric strength and high resistivity. PFCs can be non-flammable and are generally mechanically compatible with materials of construction, exhibiting limited solvency. Additionally, PFCs generally exhibit low toxicity and good operator friendliness. PFCs can be manufactured in such a way as to yield a product that has a narrow molecular weight distribution. PFCs and PFPEs can exhibit one important disadvantage, however, and that is long environmental persistence which can give rise to high global warming potentials. Materials currently used as heat-transfer fluids for cooling electronics or electrical equipment include PFCs, PFPEs, silicone oils, and hydrocarbon oils. Each of these heat-transfer fluids has some disadvantage. PFCs and PFPEs may be environmentally persistent. Silicone oils and hydrocarbon oils are typically flammable.

The use of fluorinated oxiranes for fire extinguishing has been disclosed, for example, in U.S. Ser. No. 61/431,119 entitled “Fluorinated Oxiranes as Fire Extinguishing Compositions and Methods of Extinguishing Fires Therewith”, filed Jan. 10, 2011. The use of fluorinated oxiranes as dielectric fluids has been disclosed, for example, in U.S. Ser. No. 61/435,867 entitled “Fluorinated Oxiranes as Dielectric Fluids”, filed Jan. 25, 2011. Lubricants containing fluorinated oxiranes has been disclosed, for example, in U.S. Ser. No. 61/448,826 entitled “Lubricant Compositions Containing Fluorooxiranes”, filed Mar. 10, 2011. The use of fluorinated oxiranes as organic working fluids in Rankine cycle systems is disclosed in Applicants' copending application, U. S. Attorney Docket No., 67219US002, entitled “Fluorinated Oxiranes as Organic Rankine Cycle Working Fluids and Methods of Using Same”, which was filed on the same date herewith.

### SUMMARY

There continues to be a need for heat transfer fluids which are suitable for the high temperature needs of the marketplace such as, for example, use in vapor phase soldering. There is also a continuing need for heat transfer fluids that have thermal stability at the temperature of use and that have a short atmospheric lifetime so that they have a reduced global warming potential. The provided fluorinated oxiranes perform well as heat transfer fluids at high temperature and yield products that can be consistently made. Additionally, they can be thermally stable at use temperatures, typically from −50° C. to 130° C. and even, in some embodiments, at temperatures of up to about 230° C., and have relatively shorter atmospheric lifetimes than conventional materials.

There is also a need for apparatuses and processes for high temperature heat transfer that include these fluorinated oxiranes.

In this disclosure:

“in-chain heteroatom” refers to an atom other than carbon (for example, oxygen and nitrogen) that is bonded to carbon atoms in a carbon chain so as to form a carbon-heteroatom-carbon chain;

“device” refers to an object or contrivance which is heated, cooled, or maintained at a predetermined temperature;

“inert” refers to chemical compositions that are generally not chemically reactive under normal conditions of use;

“mechanism” refers to a system of parts or a mechanical appliance;

“fluorinated” refers to hydrocarbon compounds that have one or more C—H bonds replaced by C—F bonds;

“oxirane” refers to a substituted hydrocarbon that contains at least one epoxy group; and

“perfluoro—” (for example, in reference to a group or moiety, such as in the case of “perfluoroalkylene” or “perfluoroalkylcarbonyl” or “perfluorinated”) means completely fluorinated such that, except as may be otherwise indicated, there are no carbon-bonded hydrogen atoms replaceable with fluorine.

In one aspect, an apparatus for heat transfer is provided that includes a device; and a mechanism for transferring heat to or from the device, the mechanism comprising a heat transfer fluid that includes a fluorinated oxirane. The fluorinated oxirane can contain substantially no hydrogen atoms bonded to carbon atoms and can have a total of from about 4 to about 12 carbon atoms. The mechanism can transfer heat to or from a device or, in some embodiments, can maintain the device at a selected temperature.

In another aspect, a method of transferring heat is provided that includes providing a device and transferring heat to or from the device using a mechanism, the mechanism comprising: a heat transfer fluid, wherein the heat transfer fluid includes a fluorinated oxirane. The fluorinated oxirane can have the same limitations as discussed in the summary of the apparatus above.

The provided fluorinated oxiranes provide compounds that can be useful in heat transfer fluids. The provided fluorinated oxiranes have surprisingly good thermal stability. They also have high dielectric strength, low electrical conductivity, chemical inertness, hydrolytic stability, and good environmental properties. The provided fluorochemical oxiranes can also be useful in vapor phase soldering.

The above summary is not intended to describe each disclosed embodiment of every implementation of the present invention. The detailed description which follows more particularly exemplifies illustrative embodiments.

### BRIEF DESCRIPTION OF THE DRAWINGS

FIG. 1a is a graph of the kinematic viscosity of provided fluorinated oxiranes having six carbons.

FIG. 1b is a graph of the kinematic viscosity of provided fluorinated oxiranes having nine carbons.

### DETAILED DESCRIPTION

In the following description, it is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

For low temperature applications, there is a need for stable materials that have low pour points and workable viscosities at low temperatures. Typically, there is a need for inert materials that have pour points less than about −50° C. Some hydrofluoroethers have been disclosed as heat-transfer fluids. Exemplary hydrofluoroethers can be found in U. S. Pat. Appl. Publ. Nos. 2010/0108934 and 2008/0139683 (Flynn et al.), 2007/0267464 (Vitcak et al.), and U.S. Pat. Nos. 7,128,133 and 7,390,427 (both Costello et al.). However, the need exists for a heat-transfer fluid which is inert, has high dielectric strength, low electrical conductivity, chemical inertness, thermal stability and effective heat transfer, is liquid over a wide temperature range, has good heat-transfer properties over a wide range of temperatures and also has a reasonably short atmospheric lifetime so that its global warming potential is relatively low.

The fluorinated oxirane compounds are believed to possess the required stability as well as the necessary short atmospheric lifetime and lower global warming potential than perfluorocarbons which makes them viable candidates for these high temperature heat transfer applications. Fluorinated oxiranes useful in the provided compositions and processes can be oxiranes that have a carbon backbone which is fully fluorinated (perfluorinated), i.e., substantially all of the hydrogen atoms in the carbon backbone have been replaced with fluorine or oxiranes that can have a carbon backbone which is fully or partially fluorinated having, in some embodiments, up to a maximum of three hydrogen atoms.

In addition to providing the required stability for use in heat transfer applications, the fluorinated oxiranes also demonstrate desirable environmental benefits. Many compounds that display high stability in use have also been found to be quite stable in the environment.

Perfluorocarbons and perfluoropolyethers exhibit high stability but also have been shown to have long atmospheric lifetimes which result in high global warming potentials. The atmospheric lifetimes of C₆F₁₄ and CF₃OCF(CF₃)CF₂OCF₂OCF₃ are reported as 3200 years and 800 years, respectively (see Climate Change 2007: The Physical Science Basis. Contribution of Working Group I to the Fourth Assessment Report of the Intergovernmental Panel on Climate Change, Solomon, S., D. Qin, M. Manning, Z. Chen, M. Marquis, K. B. Averyt, M. Tignor and H. L. Miller (eds.), Cambridge University Press, Cambridge, United Kingdom and New York, N.Y., USA, 996 pp, 2007.). The fluorinated oxiranes have been found to degrade in the environment on timescales that result in significantly reduced atmospheric lifetimes and lower global warming potentials compared to perfluorocarbons and perfluoropolyethers. Based on kinetic studies for reaction with hydroxyl radical, 2,3-difluoro-2-(1,2,2,2-tetrafluoro-l-trifluoromethyl-ethyl)-3-trifluoromethyl-oxirane has an estimated atmospheric lifetime of 20 years. In similar kinetic studies, 2-fluoro-2-pentafluoroethyl-3,3-bis-trifluoromethyl-oxirane demonstrates an estimated atmospheric lifetime of 77 years. As a result of their shorter atmospheric lifetimes, fluorinated oxiranes have lower global warming potentials and would be expected to make significantly less contribution to global warming as compared to perfluorocarbons and perfluoropolyethers.

In applications where the direct contact of energized, electronic components by the heat transfer fluid occurs, whether intended or otherwise, the need exists for fluids with dielectric breakdown strengths greater than around 8 megavolts/meter (MV/m), measured according to ASTM D877. Such high dielectric breakdown strengths help to avoid damage to the electronic components through short circuits. The provided fluorinated oxirane compounds possess the required dielectric properties for direct contact with energized, electronic components.

The provided fluorinated oxiranes can be derived from fluorinated olefins that have been oxidized with epoxidizing agents. In the provided fluorinated oxirane compositions the carbon backbone includes the whole carbon framework including the longest hydrocarbon chain (main chain) and any carbon chains branching off of the main chain. In addition, there can be one or more catenated heteroatoms interrupting the carbon backbone such as oxygen and nitrogen, for example ether or trivalent amine functionalities. The catenated heteroatoms are not directly bonded to the oxirane ring. In these cases the carbon backbone includes the heteroatoms and the carbon framework attached to the heteroatom.

Typically, the majority of halogen atoms attached to the carbon backbone are fluorine; most typically, substantially all of the halogen atoms are fluorine so that the oxirane is a perfluorinated oxirane. The provided fluorinated oxiranes can have a total of 4 to 12 carbon atoms. Representative examples of fluorinated oxirane compounds suitable for use in the provided processes and compositions include 2,3-difluoro-2,3-bis-trifluoromethyl-oxirane, 2,2,3-trifluoro-3-pentafluoroethyl-oxirane, 2,3-difluoro-2-(1,2,2,2-tetrafluoro-1-trifluoromethyl-ethyl)-3-trifluoromethyl-oxirane, 2-fluoro-2-pentafluoroethyl-3,3-bis-trifluoromethyl-oxirane, 1,2,2,3,3,4,4,5,5,6-decafluoro-7-oxa-bicyclo[4.1.0]heptane, 2,3-difluoro-2-trifluoromethyl-3-pentafluoroethyl-oxirane, 2,3-difluoro-2-nonafluorobutyl-3-trifluoromethyl-oxirane, 2,3-difluoro-2-heptafluoropropyl-3-pentafluoroethyl-oxirane, 2-fluoro-3-pentafluoroethyl-2,3-bis-trifluoromethyl-oxirane, 2,3-bis-pentafluoroethyl-2,3-bistrifluoromethyl-oxirane, 2,3-bis-trifluoromethyl-oxirane, 2-pentafluoroethyl-3-trifluoromethyl-oxirane, 2-(1,2,2,2-tetrafluoro-1-trifluoromethyl-ethyl)-3-trifluoromethyl-oxirane, 2-nonafluorobutyl-3-pentafluoroethyl-oxirane, 2-fluoro-2-trifluoromethyl-oxirane, 2,2-bis-trifluoromethyl-oxirane, 2-fluoro-3-trifluoromethyl-oxirane, 2-heptafluoroisopropyloxirane, 2-heptafluoropropyloxirane, 2-nonafluorobutyloxirane, 2-tridecafluorohexyloxirane, and oxiranes of HFP trimer including 2-pentafluoroethyl-2-(1,2,2,2-tetrafluoro-1-trifluoromethyl-ethyl)-3,3-bis-trifluoromethyl-oxirane, 2-fluoro-3,3-bis-(1,2,2,2-tetrafluoro-l-trifluoromethyl-ethyl)-2-trifluoromethyl-oxirane, 2-fluoro-3-heptafluoropropyl-2-(1,2,2,2-tetrafluoro-1-trifluoromethyl-ethyl)-3-trifluoromethyl-oxirane, 2-(1,2,2,3,3,3-hexafluoro-1-trifluoromethyl-propyl)-2,3,3-tris-trifluoromethyl-oxirane and 2-[1,1,2,3,3,3-hexafluoro-2-(trifluoromethyl)propyl]-2-(trifluoromethyl)oxirane.

The provided fluorinated oxirane compounds can be prepared by epoxidation of the corresponding fluorinated olefin using an oxidizing agent such as sodium hypochlorite, hydrogen peroxide or other well known epoxidizing agent such as peroxycarboxylic acids such as meta-chloroperoxybenzoic acid or peracetic acid. The fluorinated olefinic precursors can be directly available as, for example, in the cases of 1,1,1,2,3,4,4,4-octafluoro-but-2-ene (for making 2,3-difluoro-2,3-bis-trifluoromethyl oxirane), 1,1,1,2,3,4,4,5,5,5-decafluoro-pent-2-ene (for making 2,3-difluoro-2-trifluoromethyl-3-pentafluoroethyl oxirane) or 1,2,3,3,4,4,5,5,6,6 decafluoro-cyclohexene (for making 1,2,2,3,3,4,4,5,5,6-decafluoro-7-oxa-bicyclo[4.1.0]heptane). Other useful fluorinated olefinic precursors can include oligomers of hexafluoropropene (HFP) and tetrafluoroethylene (TFE) such as dimers and trimers. The HFP oligomers can be prepared by contacting 1,1,2,3,3,3-hexafluoro-1-propene (hexafluoropropene) with a catalyst or mixture of catalysts selected from the group consisting of cyanide, cyanate, and thiocyanate salts of alkali metals, quaternary ammonium, and quaternary phosphonium in the presence of polar, aprotic solvents such as, for example, acetonitrile. The preparation of these HFP oligomers is disclosed, for example, in U.S. Pat. No. 5,254,774 (Prokop). Useful oligomers include HFP trimers or HFP dimers. HFP dimers include a mixture of cis- and trans-isomers of perfluoro-4-methyl-2-pentene as indicated in Table 1 in the Example section below. HFP trimers include a mixture of isomers of C₉F₁₈. This mixture has six main components that are also listed in Table 1 in the Example section.

The provided fluorinated oxirane compounds can have a boiling point in a range of from about −50° C. to about 230° C. In some embodiments, the fluorinated oxirane compounds can have a boiling point in the range of from about −50° C. to about 130° C. In other embodiments, the fluorinated oxiranes compounds can have a boiling range of from about 0° C. to about 55° C. Some exemplary materials and their boiling point ranges are disclosed in the Examples section below.

In some embodiments, an apparatus is provided that requires heat transfer. The apparatus includes a device and a mechanism for transferring heat to or from the device using a heat-transfer fluid. The heat-transfer fluid can be a fluorinated oxirane as described above. Exemplary apparatuses include refrigeration systems, cooling systems, testing equipment, and machining equipment. Other examples include test heads used in automated test equipment for testing the performance of semiconductor dice; wafer chucks used to hold silicon wafers in ashers, steppers, etchers, constant temperature baths, and thermal shock test baths. In yet other embodiments, the provided apparatus can include, a refrigerated transport vehicle, a heat pump, a supermarket food cooler, a commercial display case, a storage warehouse refrigeration system, a geothermal heating system, a solar heating system, an organic Rankine cycle device, and combinations thereof.

The provided apparatus includes a device. The device is defined herein as a component, work-piece, assembly, etc. to be cooled, heated or maintained at a selected temperature. Such devices include electrical components, mechanical components and optical components. Examples of devices of the present invention include, but are not limited to microprocessors, wafers used to manufacture semiconductor devices, power control semiconductors, electrical distribution switch gear, power transformers, circuit boards, multi-chip modules, packaged and unpackaged semiconductor devices, lasers, chemical reactors, fuel cells, and electrochemical cells. In some embodiments, the device can include a chiller, a heater, or a combination thereof. In other embodiments, the device can include an electronic component to be soldered and solder. Typically, the heat required for soldering can be supplied by a vapor phase that has a temperature of greater than 170° C., greater than 200° C., greater than 230° C., or even greater.

In one embodiment, the device can include equipment that is used to test the performance of semiconductor dice. The dice are the individual “chips” that are cut from a wafer of semiconductor substrate. The dice come from the semiconductor foundry and must be checked to ensure they meet functionality requirements and processor speed requirements. The test is used to sort “known good dice” (KGD) from dice that do not meet the performance requirements. This testing is generally performed at temperatures ranging from about −80° C. to about 100° C.

In some cases, the dice are tested one-by-one, and an individual die is held in a chuck. This chuck provides, as part of its design, provision for cooling the die. In other cases, several dice are held in the chuck and are tested either sequentially or in parallel. In this situation, the chuck provides cooling for several dice during the test procedure. It may be advantageous to test dice at elevated temperatures to determine their performance characteristics under conditions of elevated temperature. In this case, a heat-transfer fluid which has good cooling properties well above room temperature is advantageous. In some cases, the dice are tested at very low temperatures. For example, complementary metal-oxide semiconductor (“CMOS”) devices in particular operate more quickly at lower temperatures. If a piece of automated testing equipment (ATE) employs CMOS devices “on board” as part of its permanent logic hardware, it may be advantageous to maintain the logic hardware at a low temperature.

Therefore, to provide maximum versatility to the ATE, a heat-transfer fluid typically performs well at both low and high temperatures (i.e., typically has good heat transfer properties over a wide temperature range), is inert (i.e., is non-flammable, low in toxicity, non-chemically reactive), has high dielectric strength, has a low environmental impact, and has predictable heat-transfer properties over the entire operating temperature range.

In another embodiment, the devices can include etchers. Etchers can operate over temperatures ranging from about 70° C. to about 150° C. Typically, during etching, a reactive plasma is used to anisotropically etch features into a semiconductor. The semiconductor can include a silicon wafer or include a II-VI or a III-V semiconductor. In some embodiments, the semiconductor materials can include, for example, III-V semiconductor materials such as, for example, GaAs, InP, AlGaAs, GaInAsP, or GaInNAs. In other embodiments, the provided process is useful for etching II-VI semiconductor materials such as, for example, materials that can include cadmium, magnesium, zinc, selenium, tellurium, and combinations thereof. An exemplary II-VI semiconductor material can include CdMgZnSe alloy. Other II-VI semiconductor materials such as CdZnSe, ZnSSe, ZnMgSSe, ZnSe, ZnTe, ZnSeTe, HgCdSe, and HgCdTe can also be etched using the provided process. The semiconductors to be processed are typically kept at a constant temperature. Therefore, the heat-transfer fluid that can have a single phase over the entire temperature range is typically used. Additionally, the heat-transfer fluid typically has predictable performance over the entire range so that the temperature can be precisely maintained.

In other embodiments, the devices can include ashers that operate over temperatures ranging from about 40° C. to about 150° C. Ashers are devices that can remove the photosensitive organic masks made of positive or negative photo resists. These masks are used during etching to provide a pattern on the etched semiconductor.

In some embodiments, the devices can include steppers that can operate over temperatures ranging from about 40° C. to about 80° C. Steppers are an essential part of photolithography that is used in semiconductor manufacturing where reticules needed for manufacturing are produced. Reticules are tools that contain a pattern image that needs to be stepped and repeated using a stepper in order to expose the entire wafer or mask. Reticules are used to produce the patterns of light and shadow needed to expose the photosensitive mask. The film used in the steppers is typically maintained within a temperature window of +/−0.2° C. to maintain good performance of the finished reticule.

In yet other embodiments, the devices can include plasma enhanced chemical vapor deposition (PECVD) chambers that can operate over temperatures ranging from about 50° C. to about 150° C. In the process of PECVD, films of silicon oxide, silicon nitride, and silicon carbide can be grown on a wafer by the chemical reaction initiated in a reagent gas mixture containing silicon and either: 1) oxygen; 2) nitrogen; or 3) carbon. The chuck on which the wafer rests is kept at a uniform, constant temperature at each selected temperature.

In yet other embodiments, the devices can include electronic devices, such as processors, including microprocessors. As these electronic devices become more powerful, the amount of heat generated per unit time increases. Therefore, the mechanism of heat transfer plays an important role in processor performance. The heat-transfer fluid typically has good heat transfer performance, good electrical compatibility (even if used in “indirect contact” applications such as those employing cold plates), as well as low toxicity, low (or non-) flammability and low environmental impact. Good electrical compatibility requires the heat-transfer fluid candidate to exhibit high dielectric strength, high volume resistivity, and poor solvency for polar materials. Additionally, the heat-transfer fluid must exhibit good mechanical compatibility, that is, it must not affect typical materials of construction in an adverse manner.

The present disclosure includes a mechanism for transferring heat. The mechanism includes a provided heat transfer fluid. The heat transfer fluid includes one or more fluorinated oxiranes. Heat is transferred by placing the heat transfer mechanism in thermal contact with the device. The heat transfer mechanism, when placed in thermal contact with the device, removes heat from the device or provides heat to the device, or maintains the device at a selected temperature. The direction of heat flow (from device or to device) is determined by the relative temperature difference between the device and the heat transfer mechanism.

The heat transfer mechanism may include facilities for managing the heat-transfer fluid, including, but not limited to pumps, valves, fluid containment systems, pressure control systems, condensers, heat exchangers, heat sources, heat sinks, refrigeration systems, active temperature control systems, and passive temperature control systems. Examples of suitable heat transfer mechanisms include, but are not limited to, temperature controlled wafer chucks in plasma enhanced chemical vapor deposition (PECVD) tools, temperature-controlled test heads for die performance testing, temperature-controlled work zones within semiconductor process equipment, thermal shock test bath liquid reservoirs, and constant temperature baths. In some systems, such as etchers, ashers, PECVD chambers, vapor phase soldering devices, and thermal shock testers, the upper desired operating temperature may be as high as 170° C., as high as 200° C., or even as high as 230° C.

Heat can be transferred by placing the heat transfer mechanism in thermal contact with the device. The heat transfer mechanism, when placed in thermal contact with the device, removes heat from the device or provides heat to the device, or maintains the device at a selected temperature. The direction of heat flow (from device or to device) is determined by the relative temperature difference between the device and the heat transfer mechanism. The provided apparatus can also include refrigeration systems, cooling systems, testing equipment and machining equipment. In some embodiments, the provided apparatus can be a constant temperature bath or a thermal shock test bath.

In other aspects, a method of transferring heat is provided that includes providing a device and transferring heat to or from the device using a mechanism. The mechanism can include a heat transfer fluid such as the fluorinated oxiranes disclosed herein. The provided method can include vapor phase soldering wherein the device is an electronic component to be soldered.

Objects and advantages of this invention are further illustrated by the following examples, but the particular materials and amounts thereof recited in these examples, as well as other conditions and details, should not be construed to unduly limit this invention.

### EXAMPLES

TABLE 1
Materials

| Chemical | Description | Source |
|---|---|---|
| 1,1,1,2,3,4,5,5,5-nonafluoro- 4-trifluoromethyl-pent-2-ene | 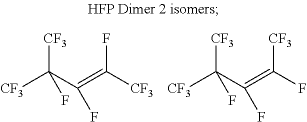 [SMILES: F/C(=C(/F)C(F)(C(F)(F)F)C(F)(F)F)C(F)(F)F ; F/C(=C(\F)C(F)(C(F)(F)F)C(F)(F)F)C(F)(F)F] | 3M Foam Additive FA-188, 3M, St. Paul, MN. |
| 1,2,3,3,4,4,5,5,6,6 | | Available from Sigma- |
| decafluoro-cyclohexene | | Aldrich, St. Louis, MO. |
| HFP Trimer | 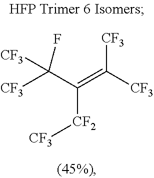 [SMILES: FC(F)(F)C(=C(C(F)(F)C(F)(F)F)C(F)(C(F)(F)F)C(F)(F)F)C(F)(F)F] | U.S. Pat. No. 5,254,774 |
| | 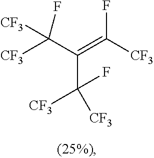 [SMILES: FC(=C(C(F)(C(F)(F)F)C(F)(F)F)C(F)(C(F)(F)F)C(F)(F)F)C(F)(F)F] | |
| | 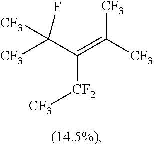 [SMILES: FC(F)(F)C(=C(C(F)(F)C(F)(F)F)C(F)(C(F)(F)F)C(F)(F)F)C(F)(F)F] | |
| | 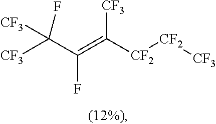 [SMILES: F/C(=C(/C(F)(F)F)C(F)(F)C(F)(F)C(F)(F)F)C(F)(C(F)(F)F)C(F)(F)F] | |
| | 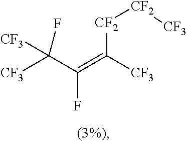 [SMILES: F/C(=C(\C(F)(F)F)C(F)(F)C(F)(F)C(F)(F)F)C(F)(C(F)(F)F)C(F)(F)F] | |
| | 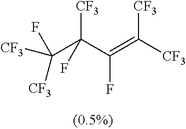 [SMILES: FC(=C(C(F)(F)F)C(F)(F)F)C(F)(C(F)(F)F)C(F)(C(F)(F)F)C(F)(F)F] | |
| Perfluorohexane | C₆F₁₄ | 3M FLUORINERT FC-72; |
| | | 3M Company, St Paul, MN |
| Dodecafluoro-2- | C₂F₅C(O)CF(CF₃)₂ | 3M NOVEC 649: 3M |
| methylpentan-3-one | | Company, St Paul, MN |
| 2-trifluoromethyl-3- | (CF₃)₂CFCF(OC₂H₅)CF₂CF₂CF₃ | 3M NOVEC 7500: 3M |
| ethoxydodecafluorohexane | | Company, St Paul, MN |
| Perfluorotripropylamine | (C₃F₇)₃N | 3M FLUORINERT |
| | | FC3283: 3M Company, St |
| | | Paul, MN |
| Perfluoro-N- | C₅F₁₁NO | 3M FLUORINERT |
| methylmorpholine | | FC3284, 3M Company, St |
| | | Paul, MN |
| Sodium Hydroxide | NaOH | GFS Chemicals, Inc., |
| | | Powell, OH |
| Sodium Hypochlorite | Na⁺[ClO]⁻ | Alfa Aesar, Ward Hill, MA |
| Potassium Hydroxide | KOH | Sigma Aldrich, Milwaukee, |
| | | WI |
| Hydrogen Peroxide | H₂O₂ | GFS Chemicals, Inc., |
| | | Powell, OH |
| Acetonitrile | CH₃CN | Honeywell Burdick & |
| | | Jackson, Morristown, NJ |

### Materials

### Example 1

### Synthesis of 2,3-difluoro-2-(1,2,2,2-tetrafluoro-1-trifluoromethyl-ethyl)-3-trifluoromethyl-oxirane. (C₆F₁₂O)

In a 1.5 liter glass reactor fitted with a mixer and a cooling jacket, 400 grams of acetonitrile, 200 grams of 1,1,1,2,3,4,5,5,5-nonafluoro-4-trifluoromethyl-pent-2-ene and 150 grams of 50% potassium hydroxide were added. The reactor temperature was controlled at 0° C. using the reactor cooling jacket. Then 100 grams of 50% hydrogen peroxide was slowly added to the reactor under strong mixing while controlling the reactor temperature at 0° C. After all the hydrogen peroxide was added within about 2 hours, the mixer was turned off to allow the product crude to phase split from solvent and aqueous phases. 155 grams of the product crude was collected from the bottom product phase. The product crude was then washed with 200 grams of water to remove solvent acetonitrile and then purified in a 40-tray Oldershaw fractionation column with condenser being cooled to 15° C. The fractionation column was operated in such a way so that the reflux ratio (the distillate flow rate going back to the fractionation column to the distillate flow rate going to the product collection cylinder) was at 10:1. The final product was collected as the condensate when the head temperature in the fractionation column was between 52° C. and 53° C.

The 90 grams of the final product collected from the method above was analyzed by 376.3 MHz ¹⁹F-NMR spectra and identified as a mixture of 2,3-difluoro-2-(1,2,2,2-tetrafluoro-1-trifluoro-methyl-ethyl)-3-trifluoromethyl-oxirane, 95.8% and 2.2% of 2-fluoro-2-pentafluoroethyl-3,3-bis-trifluoromethyl-oxirane.

### Example 2

### Oxirane Synthesis and Purification of 1,2,2,3,3,4,4,5,5,6-decafluoro-7-oxa-bicyclo [4.1.0]heptane. (cC₆F₁₂O)

In a 1.5 liter glass reactor fitted with a mixer and a cooling jacket, 400 grams of acetonitrile, 200 grams of 1,2,3,3,4,4,5,5,6,6-decafluoro-cyclohexene (89.3% purity) and 150 grams of 50% potassium hydroxide were added. The reactor temperature was controlled at 0° C. using the reactor cooling jacket. Then 100 grams of 50% hydrogen peroxide was slowly added to the reactor under strong mixing while controlling the reactor temperature at 0° C. After all the hydrogen peroxide was added within about 2 hours, the mixer was turned off to allow the product crude to phase split from solvent and aqueous phases. 100 grams of the product crude was collected from the bottom product phase. The product crude was then washed with 100 grams of water to remove solvent acetonitrile and then purified in a 40-tray Oldershaw fractionation column with condenser being cooled to 15° C. The fractionation column was operated in such a way that the reflux ratio (the distillate flow rate going back to the fractionation column to the distillate flow rate going to the product collection cylinder) was at 10:1. The final product was collected as the condensate when the head temperature in the fractionation column was between 47° C. and 55° C.

The 70 grams of the final product collected from the method above was analyzed by 376.3 MHz ¹⁹F-NMR spectra and identified as 1,2,2,3,3,4,4,5,5,6-decafluoro-7-oxa-bicyclo[4.1.0]heptane with a purity of 94.1% with an additional 2.6% isomers.

### Example 3

### C₉ Oxirane Synthesis and Purification of HFP Trimer-Oxirane (C₉F₁₈O).

In a 1.5 liter glass reactor fitted with a mixer and a cooling jacket, 400 grams of acetonitrile, 200 grams of HFP Trimer (C₉F₁₈), and 150 grams of 50% potassium hydroxide were added. The reactor temperature was controlled at 0° C. using the reactor cooling jacket. Then 100 grams of 50% hydrogen peroxide was slowly added to the reactor under strong mixing while controlling the reactor temperature between 0° C. and 20° C. After all the hydrogen peroxide was added within about 2 hours, the mixer was turned off to allow the product crude to phase split from solvent and aqueous phases. 180 grams of the product crude was collected from the bottom product phase. The product crude was then washed with 200 grams of water to remove solvent acetonitrile and then purified in a 40-tray Oldershaw fractionation column with condenser being cooled to 15° C. The fractionation column was operated in such a way so that the reflux ratio (the distillate flow rate going back to the fractionation column to the distillate flow rate going to the product collection cylinder) was at 10:1. The final product was collected as the condensate when the head temperature in the fractionation column was between 120° C. and 122° C.

The 150 grams of the final product collected from the method above was analyzed by 376.3 MHz ¹⁹F-NMR spectra and identified as oxiranes of HFP trimer (C₉F₁₈O) with 5 isomeric forms. The sum of all 5 isomers had a purity of 99.4%.

### Example 4

### Synthesis of 2-nonafluorobutyloxirane (C₄F₉CH(O)CH₂)

The oxirane was prepared according to a modification of the procedure of WO2009/096265 (Daikin Industries Ltd.). A 500 mL, magnetically stirred, three-necked round bottom flask was equipped with a water condensor, thermocouple and an addition funnel The flask was cooled in a water bath. Into the flask were placed C₄F₉CH═CH₂ (50 g, 0.2 mol, Alfa Aesar), N-bromosuccinimide (40 g, 0.22 mol, Aldrich Chemical Company) and dichloromethane as the solvent (250 mL). Chlorosulfonic acid (50 g, 0.43 mol, Alfa Aesar) was placed in the addition funnel and added slowly to the stirred reaction mixture while keeping the reaction temperature below 30° C. After the addition was completed the reaction mixture was held at ambient temperature for 16 hours. The entire reaction mixture was then poured carefully onto ice, the lower dichloromethane phase separated and washed once more with an equal volume of water and the solvent removed by rotary evaporation yielding 82 g of the chlorosulfite C₄F₉CHBrCH₂OSO₂Cl in about 65% purity by glc and which contained some C₄F₉CHBrCH₂Br. The chlorosulfite mixture was used without further purification in the next step.

The chlorosulfite, benzyltrimethylammonium chloride (0.6 g, 0.003 mol, Alfa Aesar) and water (350 mL) were placed in a 1 L, magnetically stirred, three-necked round bottom flask which was equipped with a water condensor, thermocouple and an addition funnel A solution of potassium iodide (66.3 g, 0.4 mol, EMD Chemicals Inc.) dissolved in water (66 mL) was placed in the separatory funnel and added to the chlorosulfite solution dropwise over about 1.5 hours and the mixture stirred for 16 hours at ambient temperature. Dichloromethane (300 mL) was then added, the mixture filtered and the filter cake washed with an additional 100 mL of dichloromethane. The dichloromethane layer was separated and the remaining aqueous layer extracted with an additional 200 mL of dichloromethane. The dichloromethane solvent was then removed by rotary evaporation. The residue, combined with material from another preparation, was distilled bp=66-70° C./20 torr and the distillate once again dissolved in dichloromethane and washed one time with 5% aqueous sodium bisulfite to remove iodine and the solvent removed by rotary evaporation. At this stage the desired product bromohydrin (82 g) C₄F₉CHBrCH₂OH had a purity of 87% and contained about 5% C₄F₉CHBrCH₂Br and 8% C₄F₉CHClCH₂Br.

The bromohydrin (82 g), diethyl ether solvent (200 mL) and tetrabutylammonium bromide (3.0 g, 0.009 mol, Aldrich) were placed in a 500 mL, magnetically stirred, round bottom flask equipped with a condensor and thermocouple. To this mixture was added all at once a solution of sodium hydroxide (24 g, 0.6 mol) in water (33 g). The mixture was stirred vigorously for four hours. The ether solution was then washed once with saturated sodium chloride solution and once with 5% HCl solution and subsequently dried over magnesium sulfate and the residue fractionally distilled through a concentric tube column with the fraction boiling at 101° C. collected to give a product (40.9 g) which was 88.5% the desired oxirane C₄F₉CH(O)CH₂ and 7.3% bromoolefin C₄F₉CBr═CH₂. Final purification of the epoxide by removal of most of the bromoolefin was carried out by reaction of the oxirane/bromoolefin mixture, which was degassed three times under nitrogen using a Firestone valve connected to a source of dry nitrogen and mineral oil bubbler, with 2,2′-azobis(2-methylpropionitrile) [0.5 g, 0.003 mol, Aldrich] and bromine (4.0 g, 0.025 mol, Aldrich) at 65° C. for eight hours. The reaction mixture was treated with an aqueous solution of 5% by weight sodium bisulfite to remove the excess bromine, the phases were separated and the lower phase fractionally distilled through a concentric tube column to afford the final oxirane (25 g) in 97.9% purity (b.p.=102° C.). The product identity was confirmed by GCMS, H-1 and F-19 NMR spectroscopy.

### Example 5

### Synthesis of 2-tridecafluorohexyloxirane (C₆F₁₃CH(O)CH₂)

A 1L, magnetically stirred, three-necked round bottom flask was equipped with a water condensor, thermocouple and an addition funnel The flask was cooled in a water bath. Into the flask were placed fuming sulfuric acid (20% SO₃ content) (345 g, 0.86 mol SO₃, Aldrich) and bromine (34.6 g, 0.216 mol, Aldrich). Into the addition funnel was placed C₆F₁₃CH═CH₂ (150 g, 0.433 mol, Alfa Aesar) which was added to the acid solution over a two hour period. There was no noticeable exotherm. The reaction mixture was stirred at ambient temperature for 16 hours. Water (125 g) was placed in the separatory funnel and added very cautiously over about a two hour period. The initial 5-10 g addition was extremely exothermic. Once the addition was complete, more water (50 g) was added all at once and the reaction mixture heated to 90° C. for 16 hours. Diethyl ether (300 mL) was added to the reaction mixture and the two phases separated with the lower phase containing the product. The remaining aqueous phase was extracted once more with ether (150 mL), the upper ether phase separated and combined with the previous lower phase. The ether layer was washed with 5% by weight aqueous potassium hydroxide solution and the solvent removed by rotary evaporation to give 112 g of a white crystalline solid which was about 72% C₆F₁₃CHBrCH₂OH, 8% C₆F₁₃CHBrCH₂Br and 19% (C₆F₁₃CHBrCH₂O)SO₂. This solid was distilled and the fraction collected (36 g) of boiling range=68-74° C./6 torr which was found to be 90.7% the desired bromohydrin and 9.3% the dibromide.

The bromohydrin mixture was then placed in a 250 mL, magnetically stirred, round bottom flask equipped with a water condensor and thermocouple along with tetrabutylammonium bromide (1.5 g, 0.005 mol, Aldrich) dissolved in 5 g water and a solution of 8.2 g of sodium hydroxide (0.2 mol) dissolved in 15 g water. After one hour of vigorous stirring the reaction mixture was analyzed by glc which showed about a 40% conversion of the bromohydrin to the oxirane. The reaction was stirred for an additional 5 hours. The lower aqueous phase was separated and the remaining ether phase washed once with dilute aqueous hydrochloric acid, prepared by adding a few drops of 2N aqueous HCl to 50 mL water, dried over magnesium sulfate and distilled to afford the product oxirane (12 g) C₆F₁₃CH(O)CH₂ in 98.3% purity (b.p.=144° C.) and 1.5% bromoolefin C₆F₁₃CBr═CH₂ . The product structure was confirmed by GCMS, H-1 and F-19 NMR.

### Example 6

### Preparation of 2-[1,1,2,3,3,3-hexafluoro-2-(trifluoromethyl)propyl]-2-(trifluoromethyl)oxirane (CF₃)₂CFCF₂C(CF₃)OCH₂

In a 600 mL Parr reactor, hexafluoropropene dimer (300 g, 1.0 mol 3M Company), methanol (100 g, 3.12 mol, Aldrich) and TAPEH (t-amylperoxy-2-ethylhexanoate) (4 g, 0.017 mol) were charged. The reactor was sealed and the temperature was set to 75 deg. C. After stirring for 16 hours at temperature the reactor contents were emptied and washed with water to remove excess methanol. The fluorochemical phase that was recovered was dried over anhydrous magnesium sulfate and then filtered. This reaction was repeated two additional times to generate a total of 500g of product (2,3,4,5,5,5-hexafluoro-2,4-bis(trifluoromethyl)pentan-1-ol). The crude reaction product was then purified by fractional distillation using a 15-tray Oldershaw column. The fluorinated alcohol product, 2,3,4,5,5,5-hexafluoro-2,4-bis(trifluoromethyl)pentan-l-ol (257 g 0.77 mol) was charged to a 1 L round bottom flask equipped with magnetic stirring, cold water condenser, thermocouple (J-Kem controller) and an addition funnel Thionyl chloride (202.25 g, 1.7 mol, Aldrich) was charged via the addition funnel to the fluorinated alcohol at room temperature. Once the addition was complete the temperature was increased to 85 deg. C until no more offgas was observed. The water condenser was removed and a 1-plate distillation apparatus was put in place. The excess thionyl chloride was then distilled from the reaction mixture. 300 g of the product was collected. This product was charged to a flask containing 150 g of potassium fluoride in 500 mL of N-methyl-pyrrolidinone solvent. The reaction mixture was then stirred overnight at 35 deg. C. The following day the reaction flask was set up for distillation and the product 3,3,4,5,5,5-hexafluoro-2,4-bis(trifluoromethyl)pent-1-ene was distilled from the reaction flask. A total of 140 g was collected.

In a 500 mL jacketed reaction flask equipped with overhead stirring, cold water condenser, N2 bubbler and thermocouple, sodium hydroxide (2.5 g, 0.0636 mol, Aldrich), sodium hypocholorite (12% concentration 80 g, 0.127 mol), Aliquat 336 (1 g, Alfa-Aesar) were charged. The flask was cooled to 4 deg. C. The olefin, 3,3,4,5,5,5-hexafluoro-2,4-bis(trifluoromethyl)pent-1-ene (20 g 0.0636 mol) was charged to the mixture which was then stirred for 2 hours. After 2 hours, stirring was stopped and a lower FC phase was separated from the mixture. A total of 20 g of FC was collected. A sample of this was analyzed by ¹⁹F, ¹H and ¹³C NMR which confirmed the product structure for 2-[1,1,2,3,3,3-hexafluoro-2-(trifluoromethyl)propyl]-2-(trifluoromethyl)oxirane.

### Thermophysical Properties

Table II shows the thermophysical properties of some exemplary fluorinated oxiranes and comparative materials having comparable boiling points. The useful liquid range (between the pour point and the normal boiling point) of the fluorinated oxiranes (Examples 1-3) are similar to perfluorocarbons (Comparative 1), perfluoroketones (Comparative 2), and perfluoroethers (Comparative 3). The specific heat capacity of the Comparatives is also very similar to the exemplary fluorinated oxiranes.

TABLE II
Thermophysical Properties of Fluorinated Oxiranes and Comparative Materials

| | | Normal | | | Vapor | Specific |
|---|---|---|---|---|---|---|
| | | Boiling | Pour | Viscosity | Pressure | Heat |
| | | Point | Point | @ 25° C. | @ 25° C. | Capacity |
| Example | Material | (° C.) | (° C.) | (×10⁻⁷ m²/s) | kPa | (J/kg-K) |
| Comparative 1 | C₆F₁₄ | 56 | −90 | 3.8 | 30.0 | 1100 |
| Comparative 2 | C₂F₅C(O)C | 49 | −108 | 4.0 | 40.4 | 1103 |
| | F(CF₃)₂ | | | | | |
| Example 1 | C₆F₁₂O | 51.7 | −145 | 3.7 | 36.0 | 1145 |
| Example 2 | cC₆F₁₂O | 56.1 | −88 | 6.6 | 30.3 | 1083 |
| Comparative 3 | C₇F₁₅OC₂H₅ | 128 | −100 | 7.7 | 2.1 | 1128 |
| Comparative 4 | (C₃F₇)₃N | 130 | −50 | 7.5 | 1.4 | 1100 |
| Example 3 | C₉F₁₈O | 121.9 | −103 | 12.5 | 1.6 | 869 |

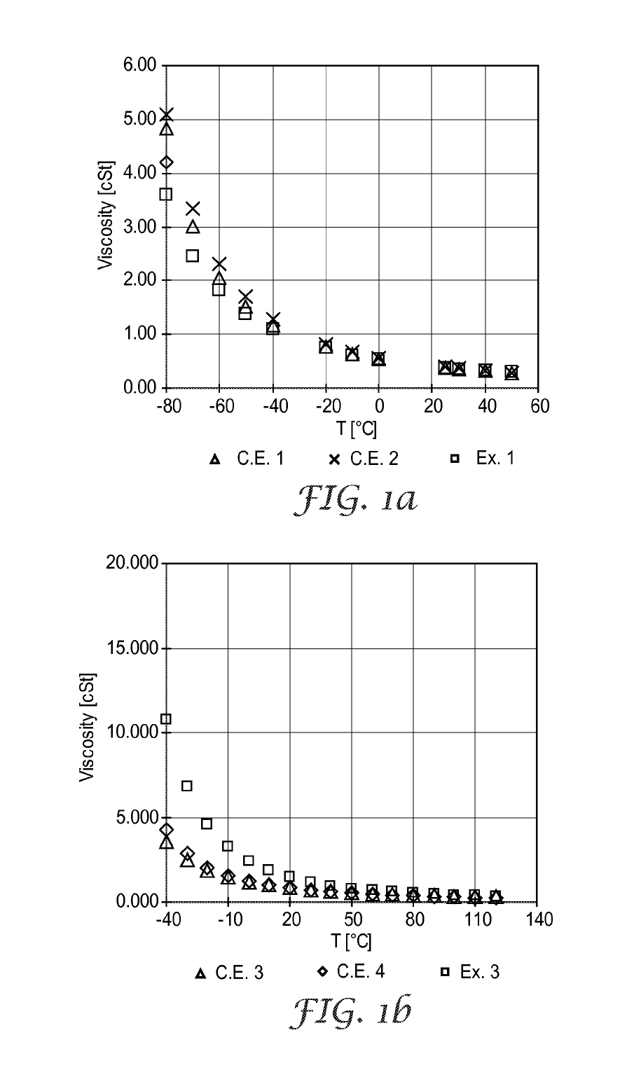

The viscosity impacts the heat transfer performance and liquid pumping power. FIG. 1 shows a comparison of the kinematic viscosity of an exemplary fluorinated oxirane having six carbon atoms (Example 1, Ex. 1) with fluids that are close in boiling point (Comparatives 1 and 2, C.E.1 and C.E.2). Examples 1 and 2 show better low temperature viscosity which can be advantageous in low temperature applications. FIG. 2 shows a comparison of the kinematic viscosity of an exemplary fluorinated oxirane (Example 3, Ex. 3) having nine carbons compared to a hydrofluoroether compound (Comparative 3, C.E. 3) and a perfluoroamine compound (Comparative 4, C.E.4). Example 3 has acceptable viscosity for heat transfer applications as low as −40° C.

### Hydrolytic Stability

Example 1 and Comparatives 1 and 2 were tested for hydrolytic stability at room temperature (˜25° C.) and 50° C. Room temperature testing was conducted by placing 5 grams of test material along with 5 grams of deionized water in new polypropylene, centrifuge tubes which were then sealed and agitated for 30 minutes using a shaker set at low speed. Elevated temperature testing was carried out by placing 5 grams of test material along with 5 grams deionized water in a clean monel pressure vessel which was sealed and placed in a convection oven set at 50° C. for 4 hours. After aging, the fluoride concentrations were determined by mixing 0.5 ml of the water phase from each sample with 0.5 ml of TISAB II buffer solution and measuring fluoride ion concentration using a calibrated fluoride selective electrode connected to a pH/millivolt meter (both the electrode and buffer solutions are available from Thermo Scientific Orion, Beverly, Mass.). The hydrolytic stability of Example 1, Comparative Example 1 and Comparative Example 2 were determined and are reported as parts per million by weight (ppmw) of fluorine in Table III below.

Results show that the hydrolytic stability of example 1 is comparable to that of comparative 1 and better than comparative 2.

TABLE III
Hydrolytic Stability of Fluorinated Oxiranes

| | F concentration after | F concentration after |
|---|---|---|
| Sample | 30 min at 25° C. (ppmw) | 4 hours at 50° C. (ppmw) |
| Comparative 1 | 0.09 | 0.23 |
| Comparative 2 | 1.13 | 5.89 |
| Example 1 | 0.14 | 0.13 |

### Thermal Stability

Thermal stability of Example 1 and perfluoro-N-methylmorpholine (FLUORINERT FC-3284, available from 3M Company, St. Paul Minn.) was determined by placing 10 grams of material to be tested in a clean, 40 ml monel pressure vessel and sealing tightly. The pressure vessel was then placed in a convection oven set at 200° C. for 16 hours. Fluoride ion concentrations were then measured as previously described. The fluoride ion concentration determined for Example 1 and FC-3284 were both less than 0.2 ppmw.

### Dielectric Breakdown Strength

The dielectric breakdown strengths of Example 1 and 3 were determined according to ASTM D877, using a model LD60 liquid dielectric test set available from Phenix Technologies, Accident, Md. The breakdown strengths for example 1 and 3 were 15.5 MV/m and 17.3 MV/m respectively.

Following are exemplary embodiments of fluorinated oxiranes as heat transfer fluids according to aspects of the present invention.

Embodiment 1 is an apparatus for heat transfer comprising: a device; and a mechanism for transferring heat to or from the device, the mechanism comprising a heat transfer fluid that comprises a fluorinated oxirane.

Embodiment 2 is an apparatus for heat transfer according to embodiment 1, wherein the fluorinated oxirane includes up to a maximum of three hydrogen atoms

Embodiment 3 is an apparatus for heat transfer according to embodiment 2, wherein the fluorinated oxirane contains substantially no hydrogen atoms bonded to carbon atoms.

Embodiment 4 is an apparatus for heat transfer according to embodiment 1, wherein the fluorinated oxirane has a total of from about 4 to about 12 carbon atoms.

Embodiment 5 is an apparatus for heat transfer according to embodiment 1, wherein the device is selected from a microprocessor, a semiconductor wafer used to manufacture a semiconductor device, a power control semiconductor, an electrochemical cell (including a lithium-ion cell), an electrical distribution switch gear, a power transformer, a circuit board, a multi-chip module, a packaged or unpackaged semiconductor device, a fuel cell, and a laser.

Embodiment 6 is an apparatus according to embodiment 1, wherein the mechanism transfers heat to the device.

Embodiment 7 is an apparatus according to embodiment 1, wherein the mechanism transfers heat from the device.

Embodiment 8 is an apparatus according to embodiment 1, wherein the mechanism maintains the device at a selected temperature.

Embodiment 9 is an apparatus according to embodiment 1, wherein the mechanism for transferring heat is a component in a system for cooling the device, wherein the system is selected from a system for cooling wafer chucks in PECVD tools, a system for controlling temperature in test heads for die performance testing, a system for controlling temperatures within semiconductor process equipment, a thermal shock testing of an electronic device, and a system for maintaining a constant temperature of an electronic device.

Embodiment 10 is an apparatus according to embodiment 1 wherein the device comprises an electronic component to be soldered and solder.

Embodiment 11 is an apparatus according to embodiment 10, wherein the mechanism comprises vapor phase soldering.

Embodiment 12 is a method of transferring heat comprising: providing a device; and transferring heat to or from the device using a mechanism, the mechanism comprising: a heat transfer fluid, wherein the heat transfer fluid, the mechanism comprising a heat transfer fluid that comprises a fluorinated oxirane.

Embodiment 13 is a method of transferring heat according to embodiment 12, wherein the fluorinated oxirane compound contains substantially no hydrogen atoms bonded to carbon atoms.

Embodiment 14 is a method of transferring heat according to embodiment 13, wherein the fluorinated oxirane compound includes a maximum of three hydrogen atoms.

Embodiment 15 is a method of vapor phase soldering according to embodiment 12, wherein the device is an electronic component to be soldered.

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows. All references cited in this disclosure are herein incorporated by reference in their entirety.

What is claimed is:

1. An apparatus for heat transfer comprising:
a device; and
a mechanism for transferring heat to or from the device, the mechanism comprising a heat transfer fluid that comprises a fluorinated oxirane.

2. An apparatus for heat transfer according to claim 1, wherein the fluorinated oxirane includes up to a maximum of three hydrogen atoms

3. An apparatus for heat transfer according to claim 2, wherein the fluorinated oxirane contains substantially no hydrogen atoms bonded to carbon atoms.

4. An apparatus for heat transfer according to claim 1, wherein the fluorinated oxirane has a total of from about 4 to about 12 carbon atoms.

5. An apparatus for heat transfer according to claim 1, wherein the device is selected from a microprocessor, a semiconductor wafer used to manufacture a semiconductor device, a power control semiconductor, an electrochemical cell (including a lithium-ion cell), an electrical distribution switch gear, a power transformer, a circuit board, a multi-chip module, a packaged or unpackaged semiconductor device, a fuel cell, and a laser.

6. An apparatus according to claim 1, wherein the mechanism transfers heat to the device.

7. An apparatus according to claim 1, wherein the mechanism transfers heat from the device.

8. An apparatus according to claim 1, wherein the mechanism maintains the device at a selected temperature.

9. An apparatus according to claim 1, wherein the mechanism for transferring heat is a component in a system for cooling the device, wherein the system is selected from a system for cooling wafer chucks in PECVD tools, a system for controlling temperature in test heads for die performance testing, a system for controlling temperatures within semiconductor process equipment, a thermal shock testing of an electronic device, and a system for maintaining a constant temperature of an electronic device.

10. An apparatus according to claim 1 wherein the device comprises an electronic component to be soldered and solder.

11. An apparatus according to claim 10, wherein the mechanism comprises vapor phase soldering.

12. A method of transferring heat comprising:
providing a device; and
transferring heat to or from the device using a mechanism, the mechanism comprising:
a heat transfer fluid,
wherein the heat transfer fluid, the mechanism comprising a heat transfer fluid that comprises a fluorinated oxirane.

13. A method of transferring heat according to claim 12, wherein the fluorinated oxirane compound contains substantially no hydrogen atoms bonded to carbon atoms.

14. A method of transferring heat according to claim 13, wherein the fluorinated oxirane compound includes a maximum of three hydrogen atoms.

15. A method of vapor phase soldering according to claim 12, wherein the device is an electronic component to be soldered.
